(19) United States
(12) Patent Application Publication
(10) Pub. No.: US 2011/0111964 A1
(43) Pub. Date: May 12, 2011

(54) COATED CONDUCTOR ARCHITECTURE

(76) Inventors: Quanxi Jia, Los Alamos, NM (US); Vladimir Matias, Santa Fe, NM (US); Alp T. Findikoglu, Santa Fe, NM (US); David M. Feldmann, Minnetonka, MN (US)

(21) Appl. No.: 12/850,311

(22) Filed: Aug. 4, 2010

Related U.S. Application Data
(60) Provisional application No. 61/273,546, filed on Aug. 4, 2009.

(51) Int. Cl. H01L 39/12; B32B 15/04; B32B 9/00

(52) U.S. Cl. 505/237; 428/336

(57) ABSTRACT

A simplified architecture for a superconducting coated conductor is provided and includes a substrate, a layer of titanium nitride directly upon the substrate, the layer of titanium nitride deposited by ion beam assisted deposition (IBAD), a layer of a buffer material having chemical and structural compatibility with said layer of titanium nitride, the buffer material layer directly upon the IBAD-titanium nitride layer, and a layer of a high temperature superconductive material such as YBCO.

The present invention relates to high temperature superconducting thick films on polycrystalline substrates with high J_{c}'s and I_{c}'s. The United States government has rights in this invention pursuant to Contract No. DE-AC52-06NA25396 between the United States Department of Energy and Los Alamos National Security, LLC for the operation of Los Alamos National Laboratory.

### FIELD OF THE INVENTION

### Background of the Invention

Since their initial development, coated conductor research has focused on fabricating increasing lengths of the material, while increasing the overall critical current carrying capacity. Different research groups have developed several techniques of fabricating coated conductors. Regardless of which techniques are used for the coated conductors, the goal of obtaining highly textured superconducting thick films, such as YBa₂Cu₃O₇₋ₓ (YBCO), with high supercurrent carrying capability on metal substrates remains.

In one prior approach (see US Published Patent Application 2006/0142164), a titanium nitride layer was used within a coated conductor architecture including a base substrate with an inert oxide material layer from the group of aluminum oxide, erbium oxide, and yttrium oxide on the base substrate, a layer of an oxide or oxynitride material upon the inert oxide material layer, a layer of an oriented cubic oxide material having a rock-salt-like structure such as magnesium oxide upon the layer of an oxide or oxynitride material, and, a layer of epitaxial titanium nitride upon the layer of an oriented cubic oxide material having a rock-salt-like structure. Subsequently, a buffer layer and a superconductive layer were deposited upon the epitaxial titanium nitride layer. While this configuration yielded good conductivity, it required a large number of layers. Continued interest remains in a simplified architecture having similarly good superconductivity.

Others have utilized titanium nitride layers (see Guth et al, Preparation of Conductive Buffer Architectures Based on IBAD-TiN, IEEE Transactions on Applied Superconductivity, vol. 19, no. 1, pp. 3447-3450, June 2009), but their clear teachings indicated that a yttrium oxide interlayer was necessary between the Hastelloy substrate and the IBAD-TiN layer to obtain the textured structure. Additionally, Guth et al. use a second homoepitaxial layer of the TiN upon the initial IBAD-TiN layer.

Titanium nitride layers deposited directly upon metal substrates by IBAD have been described as base substrates for subsequent deposition of semiconducting layers (see US Published Patent Application 2006/0033160), but no mention was made of deposition of superconductive materials.

### SUMMARY OF THE INVENTION

To achieve the foregoing and other objects, and in accordance with the purposes of the present invention, as embodied and broadly described herein, the present invention provides an article including a substrate, a layer of titanium nitride directly upon the substrate, said layer of titanium nitride deposited by ion beam assisted deposition (IBAD) and having a thickness of from about 5 to about 20 nanometers, and, a layer of a buffer material having chemical and structural compatibility with said layer of titanium nitride, said buffer material layer directly upon the IBAD-titanium nitride layer.

In another embodiment, the present invention, provides a superconductive article including a substrate, a layer of titanium nitride directly upon the substrate, said layer of titanium nitride deposited by ion beam assisted deposition (IBAD) and having a thickness of from about 5 to about 20 nanometers, a layer of a buffer material having chemical and structural compatibility with said layer of titanium nitride, said buffer material layer directly upon the IBAD-titanium nitride layer; and, a layer of a high temperature barium-copper oxide superconducting material, upon the buffer layer, the superconductive article characterized as having an J_{c} of at least about 1 megaamperes per square centimeter (MA/cm2).

### BRIEF DESCRIPTION OF THE DRAWINGS

FIG. 1 shows a schematic drawing of one embodiment of the superconductive article in accordance with the present invention.

FIG. 2 shows an x-ray diffraction (XRD) θ-2θ scan of a structure in accordance with the present invention.

FIG. 3 shows the x-ray ω rocking curve of a buffer layer of lanthanum manganate in a structure in accordance with the present invention.

FIG. 4 shows the x-ray φ scan on a buffer layer of lanthanum manganate in a structure in accordance with the present invention.

FIG. 5 shows an x-ray diffraction (XRD) θ-2θ scan of a coated conductor structure in accordance with the present invention.

FIG. 6 shows the x-ray ω rocking curve of a coated conductor structure in accordance with the present invention.

FIG. 7 shows the x-ray φ scan on a coated conductor structure in accordance with the present invention.

FIG. 8 shows the plot of superconductivity transition temperature of a coated conductor structure in accordance with the present invention.

FIG. 9 shows the plot of critical current density of a coated conductor structure in accordance with the present invention.

FIG. 10 shows a plot demonstrating field dependence of a coated conductor structure in accordance with the present invention.

FIG. 11 shows a plot demonstrating angle dependence of a coated conductor structure in accordance with the present invention.

FIG. 12 shows a digital representation of the transmission electron microscopy of a coated conductor structure in accordance with the present invention.

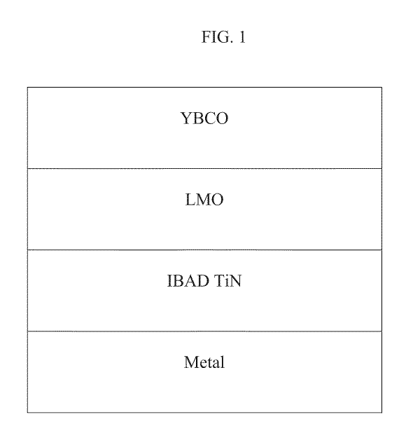

### DETAILED DESCRIPTION

The present invention concerns IBAD-TiN directly on polycrystalline metal Hastelloy substrate. This allowed the coating of superconducting YBCO films on metal substrate with only two non-superconducting layers (LaMnO₃/IBAD-TiN) between the YBCO and the metal substrate. The YBCO films grown on this simplified platform exhibited an in-plane mosaic spread less than 4° in full width at half maximum (FWHM), a critical current density above 10⁶ A/cm² at liquid nitrogen temperature, and an a value (proportional factor of critical current density H^{-α}) of around 0.33 over the field range of 0.1-1.0 Tesla (T).

The TiN layer in the ion-beam-assisted deposition is typically sputtered from a titanium nitride target. An ion-assisted, electron-beam evaporation system similar to that described by Wang et al., App. Phys. Lett., vol. 71, no. 20, pp. 2955-2957 (1997), can be used to deposit such a TiN film. Alternatively, a dual-ion-beam sputtering system similar to that described by Iijima et al., IEEE Trans. Appl. Super., vol. 3, no. 1, pp. 1510 (1993), can be used to deposit such a TiN film. Generally, the substrate normal to ion-assist beam angle is 45±3°. Generally, the thickness of the titanium nitride layer is from about 5 nm to about 20 nm, more preferably from about 10 nm to about 15 nanometers.

In an additional aspect of the present invention, it has been found that no homoepitaxial layer (of TiN) is needed to achieve good results. Such homoepitaxial layers are common following the IBAD deposition of magnesium oxide layers with the result that both an additional layer and additional deposition step become needed. Elimination of extra layers and steps is desirable.

In the high temperature superconducting film of the present invention, the substrate can be, e.g., any amorphous material or polycrystalline material. Polycrystalline materials can include materials such as a metal or a ceramic. Such ceramics can include, e.g., materials such as polycrystalline aluminum oxide or polycrystalline zirconium oxide. Preferably, the substrate can be a polycrystalline metal (e.g., metal alloys including (1) nickel-based alloys such as various Hastelloy metals, Haynes metals, and Inconel metals, (2) iron-based metals such as steels and stainless steels, or (3) copper-based metals such as copper-beryllium alloys, etc). The metal substrate on which the superconducting material is eventually deposited should preferably allow for the resultant article to be flexible whereby superconducting articles (e.g., coils, motors or magnets) can be shaped. Other substrates such as rolling assisted biaxially textured substrates (RABiTS) may be used as well.

As a lattice mismatch exists between the IBAD-TiN material and the latter deposited superconductor layer, a buffer layer is used to reduce this mismatch. This buffer layer may be formed of various materials such as lanthanum manganate (LaMnO₃), cerium oxide, YSZ (yttria-stabilized zirconia) strontium ruthenate (SrRuO₃), and the like. Preferably, the buffer layer is lanthanum manganate with the IBD-TiN. The buffer layer may be deposited by various physical vapor deposition techniques.

In the present invention, the high temperature superconducting (HTS) material is generally YBCO, e.g., YBa₂Cu₃O_{7-Δ}, Y₂Ba₄Cu₇O₁₄₊ₓ, or YBa₂Cu₄O₈, although other minor variations of this basic superconducting material, such as use of other rare earth metals as a substitute for some or all of the yttrium, may also be used. A mixture of the rare earth metal europium with yttrium may be one preferred combination. Other superconducting materials such as bismuth and thallium based superconductor materials may also be employed. YBa₂Cu₃O_{7-Δ}is generally preferred as the superconducting material.

High temperature superconducting (HTS) layers, e.g., a YBCO layer, can be deposited, e.g., by pulsed laser deposition or by methods such as evaporation including coevaporation, e-beam evaporation and activated reactive evaporation, sputtering including magnetron sputtering, ion beam sputtering and ion assisted sputtering, cathodic arc deposition, chemical vapor deposition, organometallic chemical vapor deposition, plasma enhanced chemical vapor deposition, molecular beam epitaxy, a sol-gel process, a solution process and liquid phase epitaxy. Post-deposition anneal processes are necessary with some deposition techniques to obtain the desired superconductivity.

The thin films of high temperature superconducting materials are generally from about 0.2 microns to about 10 microns in thickness, more preferably in the range of from about 1.5 microns to about 5 microns.

In pulsed laser deposition, powder of the material to be deposited can be initially pressed into a disk or pellet under high pressure, generally above about 1000 pounds per square inch (PSI) and the pressed disk then sintered in an oxygen atmosphere or an oxygen-containing atmosphere at temperatures of about 950° C. for at least about 1 hour, preferably from about 12 to about 24 hours. An apparatus suitable for pulsed laser deposition is shown in Appl. Phys. Lett. 56, 578 (1990), “Effects of Beam Parameters on Excimer Laser Deposition of YBa₂Cu₃O_{7-Δ}”, such description hereby incorporated by reference.

Suitable conditions for pulsed laser deposition include, e.g., the laser, such as an excimer laser (20 nanoseconds (ns), 248 or 308 nanometers (nm)), targeted upon a rotating pellet of the target material at an incident angle of about 45°. The substrate can be mounted upon a heated holder rotated at about 0.5 rpm to minimize thickness variations in the resultant film or coating. The substrate can be heated during deposition at temperatures from about 600° C. to about 950° C., preferably from about 740° C. to about 765° C. where YBCO is the superconducting material. An oxygen atmosphere of from about 0.1 millitorr (mTorr) to about 10 Torr, preferably from about 100 to about 250 mTorr, can be maintained within the deposition chamber during the deposition. Distance between the substrate and the pellet can be from about 4 centimeters (cm) to about 10 cm.

The deposition rate of the film can be varied from about 0.1 angstrom per second (A/s) to about 200 A/s by changing the laser repetition rate from about 0.1 hertz (Hz) to about 200 Hz. Generally, the laser beam can have dimensions of about 1 millimeter (mm) by 4 mm with an average energy density of from about 1 to 4 joules per square centimeter (J/cm²). After deposition, the films generally are cooled within an oxygen atmosphere of greater than about 100 Torr to room temperature.

The measure of current carrying capacity is called “critical current” and is abbreviated as I_{c}, measured in Amperes (A), and “critical current density” is abbreviated as J_{c}, measured in Amperes per square centimeter (A/cm²). As a width normalized value, sometimes I_{c} can be reported in amperes per centimeter-width (A/cm-width) with width referring to the dimensions of the superconducting material. In this way, values may be more meaningfully compared between different samples.

The present invention is more particularly described in the following examples which are intended as illustrative only, since numerous modifications and variations will be apparent to those skilled in the art.

### EXAMPLE 1

Electropolished Hastelloy tape was used as the substrate. IBAD-TiN (˜10-15 nm) was grown directly on Hastelloy tape. Ion beam (750 V) was at 45° to the substrate for IBAD-TiN deposition. Before the IBAD-TiN deposition, an ion beam treatment of the tape was carried out at 1000 V and 100 mA on a 22-cm source (2 mA/cm²). The gas flow in the ion gun was 7 sccm for Ar and 12 sccm for N₂. An 80 second treatment at 45° to the sample was done under such conditions. RHEED picture showed an amorphous background during such treatment. The higher argon flow appears to be beneficial due to increased damage to the surface.

### EXAMPLE 2

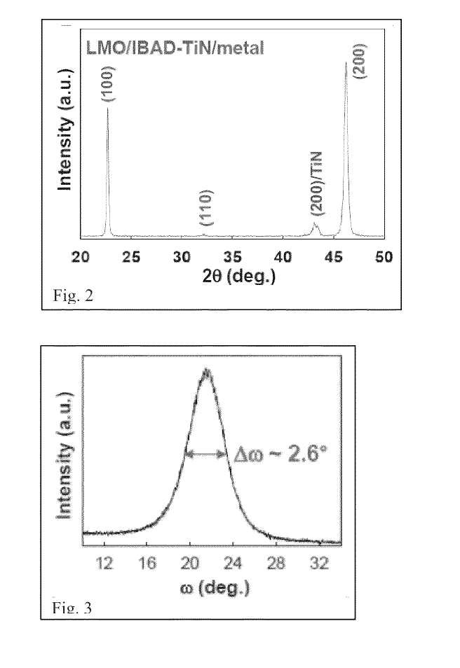

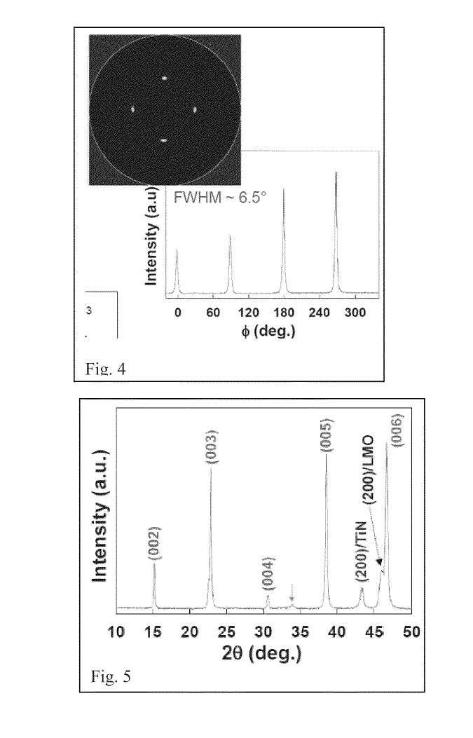

PLD was used to deposit LaMnO₃ (LMO) buffer layer directly on IBAD-TiN. The typical deposition conditions were the following: substrate temperature of from about 750° C. to about 810° C., and oxygen pressure from about 10 mTorr to about 100 mTorr. An oxygen pressure of about 40 mTorr and a substrate temperature of about 770° C. were found to give better results. The LMO deposited under such conditions had an out-of-plane Dw less than 3.0 degrees, and an in-plane Df less than 7 degrees (see FIGS. 2, 3, and 4).

### EXAMPLE 3

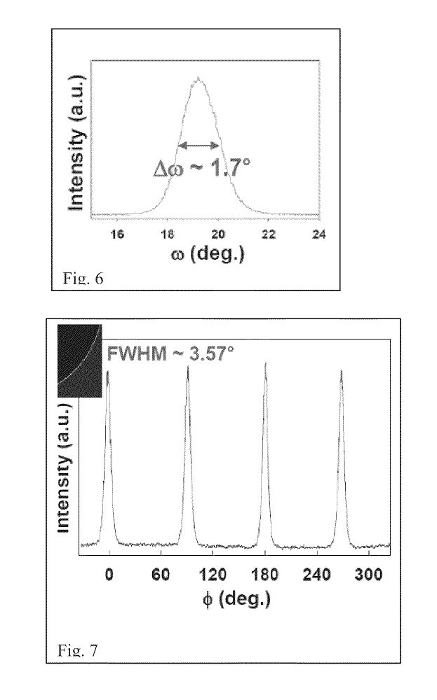

PLD was used to deposit YBCO films directly on the LMO/IBAD-TiN. The typical deposition conditions were the following: substrate temperature of from about 750° C. to about 775° C., and oxygen pressure from about 100 mTorr about 300 mTorr. An oxygen pressure of about 200 mTorr and a substrate temperature of about 755° C. were found to give better results. The YBCO deposited under such conditions had an out-of-plane Dw less than 2.0 degrees, and an in-plane Df less than 4 degrees (see FIGS. 5, 6, and 7).

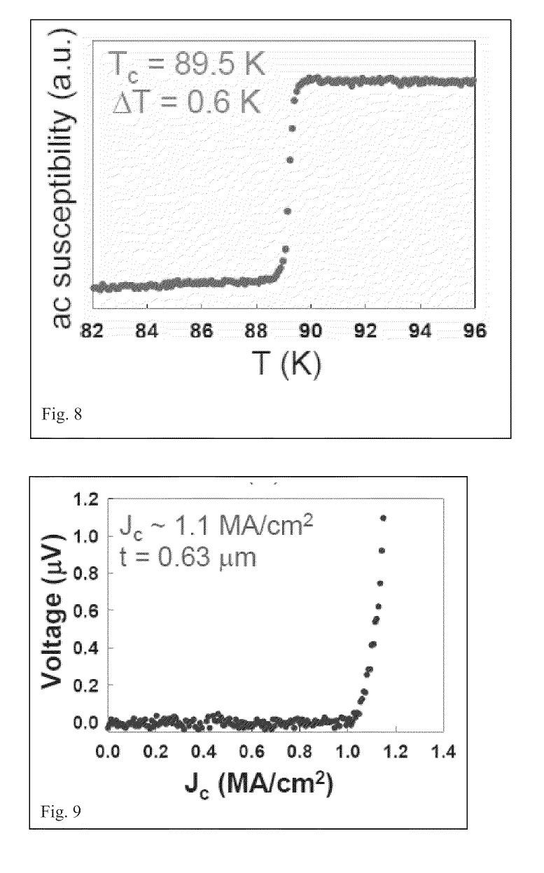

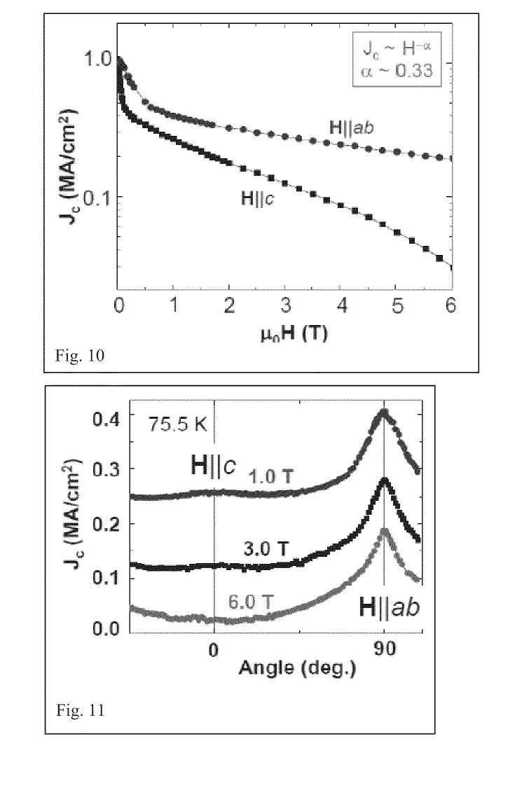

The YBCO films deposited on such a 2-layer stack also showed good superconducting properties. For example, the YBCO films had a transition temperature around 89.5 K with a transition width less than 1.0 degree (see FIG. 8). The critical current density was high than 10⁶ A/cm² at 75.5 K (see FIG. 9). The field dependence and angle dependence of the YBCO films were also good (see FIGS. 10 and 11).

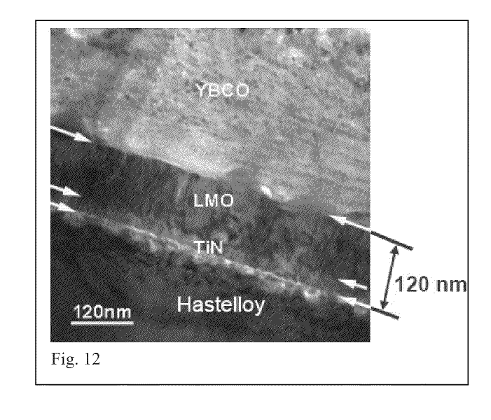

Transmission electron microscopy showed well defined interfaces crossing IBAD-TiN/LMO and LMO/YBCO (as shown in FIG. 12).

Although the present invention has been described with reference to specific details, it is not intended that such details should be regarded as limitations upon the scope of the invention, except as and to the extent that they are included in the accompanying claims.

What is claimed is:

1. An article comprising:
a substrate;
a layer of titanium nitride directly upon the substrate, said layer of titanium nitride deposited by ion beam assisted deposition (IBAD) and having a thickness of from about 5 to about 20 nanometers; and,
a layer of a buffer material having chemical and structural compatibility with said layer of titanium nitride, said buffer material layer directly upon the IBAD-titanium nitride layer.

2. The article of claim 1 wherein the substrate is a flexible polycrystalline metal.

3. The article of claim 1 wherein the buffer material is lanthanum manganate.

4. The article of claim 2 wherein the buffer material is lanthanum manganate.

5. A superconductive article comprising:
a substrate;
a layer of titanium nitride directly upon the substrate, said layer of titanium nitride deposited by ion beam assisted deposition and having a thickness of from about 5 to about 20 nanometers;
a layer of a buffer material having chemical and structural compatibility with said layer of titanium nitride directly upon the IBAD-titanium nitride layer; and,
a layer of superconductive material.

6. The superconductive article of claim 5 wherein the substrate is a flexible polycrystalline metal.

7. The superconductive article of claim 5 wherein the buffer material is lanthanum manganate.

8. The superconductive article of claim 6 wherein the buffer material is lanthanum manganate.

9. The superconductive article of claim 5 wherein the superconductive material is YBCO.
